(19) United States
(12) Patent Application Publication
(10) Pub. No.: US 2026/0362815 A1
(43) Pub. Date: Nov. 12, 2026

(54) SEMICONDUCTOR DEVICE

(71) Applicant: Samsung Electronics Co., Ltd., Suwon-si (KR)

(72) Inventors: Jeewoong Kim, Suwon-si (KR); Donghun Kim, Suwon-si (KR); Yunsuk Nam, Suwon-si (KR); Dong-Gwan Shin, Suwon-si (KR)

(73) Assignee: Samsung Electronics Co., Ltd., Suwon-si (KR)

(21) Appl. No.: 19/343,157

(22) Filed: Sep. 29, 2025

(30) Foreign Application Priority Data
May 9, 2025 (KR) 10-2025-0060578

(51) Int. Cl. H10D 89/60

(52) U.S. Cl. CPC H10D 89/711

(57) ABSTRACT

The semiconductor device includes a well extending in a first direction and having a first conductivity type, a first impurity pattern, a second impurity pattern, a third impurity pattern, and a fourth impurity pattern of a second conductivity type sequentially disposed on the well along the first direction, a first active region including a first collector/emitter region including the first impurity pattern and a second collector/emitter region including the second impurity pattern, a second active region including a third collector/emitter region including the third impurity pattern and a fourth collector/emitter region including the fourth impurity pattern, and a first bottom contact disposed on a bottom surface of the well and electrically connected to ground, and from a plan view perspective, the first bottom contact may be disposed between the first impurity pattern and the fourth impurity pattern.

### CROSS-REFERENCE TO RELATED APPLICATIONS

This present application claims priority to and the benefit under 35 U.S.C § 119(a)-(d) of Korean Patent Application No. 10-2025-0060578, filed on May 9, 2025, in the Korean Intellectual Property Office, the entire disclosure of which is incorporated herein by reference.

### FIELD

The present disclosure relates to a semiconductor device.

### BACKGROUND

An electrostatic discharge (ESD) may cause damage to an integrated circuit (IC) device. For example, damage to the IC device due to accumulated electrostatic charge may occur during testing in a manufacturing process of the IC device, during assembly of the IC device, or during use of a device in which the IC device is mounted.

A semiconductor device for protecting an IC device from an ESD may include a plurality of bipolar junction transistors. Each of the plurality of bipolar junction transistors may include a collector, an emitter, and a base. Here, a parasitic resistance inherent in the base may determine a turn-on characteristic of the bipolar junction transistor when an ESD occurs.

However, a value of the parasitic resistance inherent in the base may not be uniform in each of the plurality of bipolar junction transistors. Due to this, a difference in turn-on voltage and discharge characteristics may occur in each of the plurality of bipolar junction transistors, which may cause a problem of increased operational variation.

### SUMMARY

An objective of the present disclosure is to provide a semiconductor device with improved reliability.

An objective of the present disclosure is to provide a method of manufacturing a semiconductor device with improved reliability.

According to some embodiments of the present disclosure for solving the technical problem, a semiconductor device includes a well extending in a first direction and having a first conductivity type, a first impurity pattern, a second impurity pattern, a third impurity pattern, and a fourth impurity pattern of a second conductivity type sequentially disposed on the well along the first direction, a first active region including a first collector/emitter region including the first impurity pattern and a second collector/emitter region including the second impurity pattern, a second active region including a third collector/emitter region including the third impurity pattern and a fourth collector/emitter region including the fourth impurity pattern, and a first bottom contact disposed on a bottom surface of the well and electrically connected to ground, and from a plan view perspective, the first bottom contact may be disposed between the first impurity pattern and the fourth impurity pattern.

According to some embodiments of the present disclosure for solving the technical problem, a semiconductor device includes a well extending in a first direction and having a first conductivity type, a plurality of impurity patterns disposed on the well along the first direction and having a second conductivity type, a plurality of active regions including a collector region and an emitter region including each of the plurality of impurity patterns and disposed along the first direction, and a plurality of bottom contacts disposed on a bottom surface of the well and electrically connected to ground, and the plurality of bottom contacts may be disposed to be spaced apart from one another at a preset interval along the first direction.

According to some embodiments of the present disclosure for solving the technical problem, a semiconductor device includes a well extending in a first direction and having a first conductivity type, a first impurity pattern, a second impurity pattern, a third impurity pattern, and a fourth impurity pattern of a second conductivity type sequentially disposed on the well along the first direction, a first active region including a first collector/emitter region including the first impurity pattern and a second collector/emitter region including the second impurity pattern, a second active region including a third collector/emitter region including the third impurity pattern and a fourth collector/emitter region including the fourth impurity pattern, a first bottom contact disposed on a bottom surface of the well and electrically connected to ground, a first insulation pattern disposed on the well between the first impurity pattern and the second impurity pattern, a second insulation pattern disposed on the well between the second impurity pattern and the third impurity pattern, and a third insulation pattern disposed on the well between the third impurity pattern and the fourth impurity pattern, and from a plan view perspective, the first bottom contact is disposed between the second impurity pattern and the third impurity pattern, a distance between the first bottom contact and the second impurity pattern is approximately the same as a distance between the first bottom contact and the third impurity pattern, a distance between the first bottom contact and the first impurity pattern is approximately the same as a distance between the first bottom contact and the fourth impurity pattern, and a sidewall in the first direction of each of the first insulation pattern to the third insulation pattern may include a region where concave and convex shapes are alternately repeated.

According to some embodiments of the present disclosure for solving the technical problem, a method of manufacturing a semiconductor device includes doping a substrate with an impurity to form a well, forming a stacked structure on the substrate, patterning the stacked structure to form a trench, forming a shallow trench isolation (STI) structure in the trench, forming an impurity pattern, a sheet pattern, and a gate electrode on the well, removing the sheet pattern and the gate electrode, filling an insulating material in a region where the sheet pattern and the gate electrode were removed to form an insulation pattern, and forming a first bottom contact on a bottom surface of the well. The impurity pattern includes a first impurity pattern, a second impurity pattern, a third impurity pattern, and a fourth impurity pattern sequentially disposed along a first direction, and from a plan view perspective, the first bottom contact may be disposed between the first impurity pattern and the fourth impurity pattern.

According to some embodiments, the forming the first bottom contact on the bottom surface of the well may include disposing the first bottom contact between the second impurity pattern and the third impurity pattern from a plan view perspective.

According to some embodiments, forming the first bottom contact on the bottom surface of the well may include disposing the first bottom contact such that a distance between the first bottom contact and the second impurity pattern is approximately the same as a distance between the first bottom contact and the third impurity pattern, and a distance between the first bottom contact and the first impurity pattern is approximately the same as a distance between the first bottom contact and the fourth impurity pattern.

According to some embodiments, the method of manufacturing a semiconductor device may further include forming a first bottom insulating layer disposed on a bottom surface of the well, a second bottom insulating layer disposed on a bottom surface of the first bottom insulating layer, and a bottom wiring structure disposed on the bottom surface of the first bottom insulating layer and extending in a second direction substantially perpendicular to the first direction.

According to some embodiments, the bottom wiring structure may at least partially overlap with the second impurity pattern and the third impurity pattern in a third direction substantially perpendicular to each of the first direction and the second direction.

According to some embodiments, a width of the first bottom contact along the first direction may be less than a width of the bottom wiring structure along the first direction.

According to some embodiments, filling the insulating material in the region where the sheet pattern and the gate electrode were removed to form the insulation pattern may include forming a first insulation pattern disposed on the well between the first impurity pattern and the second impurity pattern, a second insulation pattern disposed between the second impurity pattern and the third impurity pattern, and a third insulation pattern disposed between the third impurity pattern and the fourth impurity pattern.

According to some embodiments, each of the first insulation pattern to the third insulation pattern may include a void therein.

According to some embodiments, filling the insulating material in the region where the sheet pattern and the gate electrode were removed to form the insulation pattern may include forming a region where concave and convex shapes are alternately repeated on a sidewall in the first direction of each of the first insulation pattern to the third insulation pattern.

According to some embodiments, the method of manufacturing a semiconductor device may further include removing a portion of the substrate before forming the first bottom contact.

According to some embodiments of the present disclosure, because a bottom contact is disposed on a bottom surface of a well, resistances due to the well in each of a plurality of active regions may have the same or substantially the same resistance value within a predetermined error range. Accordingly, when an ESD event occurs, each active region exhibits uniform and consistent characteristics, which may improve the reliability of the semiconductor device.

### BRIEF DESCRIPTION OF THE DRAWINGS

FIG. 1 is a circuit diagram illustrating a semiconductor device according to some embodiments of the present disclosure.

FIG. 2 is a plan view illustrating a semiconductor device according to some embodiments of the present disclosure.

FIG. 3 is a cross-sectional view taken along line A-A of FIG. 2.

FIG. 4 is a cross-sectional view taken along line B-B of FIG. 2.

FIG. 5 is a diagram illustrating a semiconductor device according to some embodiments of the present disclosure.

FIG. 6 is a diagram illustrating a semiconductor device according to some embodiments of the present disclosure.

FIGS. 7 and 8 are diagrams illustrating a semiconductor device according to some embodiments of the present disclosure.

FIG. 9 is a diagram illustrating a semiconductor device according to some embodiments of the present disclosure.

FIG. 10 is a diagram illustrating a semiconductor device according to some embodiments of the present disclosure.

FIG. 11 is a diagram illustrating a semiconductor device according to some embodiments of the present disclosure.

FIGS. 12 to 24 are diagrams illustrating a method of manufacturing a semiconductor device according to some embodiments of the present disclosure.

### DETAILED DESCRIPTION

Hereinafter, a semiconductor device according to some embodiments of the present disclosure will be described in detail with reference to the drawings.

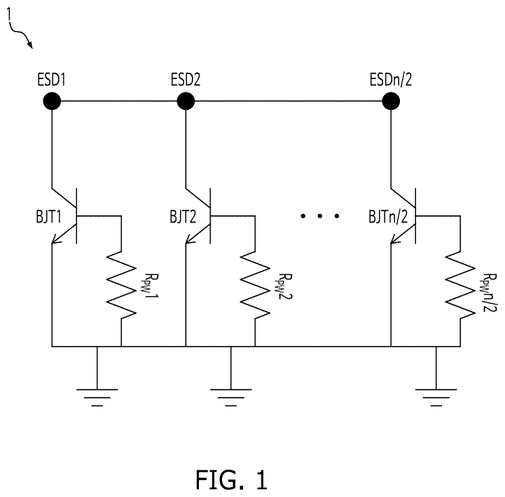

FIG. 1 is a circuit diagram illustrating a semiconductor device according to some embodiments of the present disclosure.

Referring to FIG. 1, a semiconductor device 1 may include a first bipolar junction transistor BJT1, a second bipolar junction transistor BJT2, an (n/2)-th bipolar junction transistor BJTn/2, and the like. Here, “n” means the number of active regions including a collector region and an emitter region, and may be an even number. The first bipolar junction transistor BJT1, the second bipolar junction transistor BJT2, the (n/2)-th bipolar junction transistor BJTn/2, and the like may be NPN-type bipolar junction transistors. However, the present disclosure is not limited thereto, and the first bipolar junction transistor BJT1, the second bipolar junction transistor BJT2, the (n/2)-th bipolar junction transistor BJTn/2, and the like may be PNP-type bipolar junction transistors. Hereinafter, the first bipolar junction transistor BJT1, the second bipolar junction transistor BJT2, the (n/2)-th bipolar junction transistor BJTn/2, and the like may be collectively referred to as a bipolar junction transistor BJT.

The bipolar junction transistor BJT may include a collector, a base, and an emitter. A collector of the bipolar junction transistor BJT may be connected to a first voltage terminal ESD1, ESD2, . . . ESDn/2 to which a power supply voltage of the semiconductor device 1 is provided, or to an I/O (Input/Output) terminal for input/output of data. As another example, an emitter of the bipolar junction transistor BJT may be connected to the first voltage terminal ESD1, ESD2, . . . ESDn/2 to which the power supply voltage of the semiconductor device 1 is provided, or to the I/O terminal for input/output of data.

A base of the bipolar junction transistor BJT may be connected to ground through a resistor Rpw. The resistor Rpw may correspond to a parasitic resistance inherent in a P-type doped region (e.g., a P-type well) of a substrate. However, when the bipolar junction transistor BJT is a PNP-type bipolar junction transistor, the resistor may correspond to a parasitic resistance inherent in an N-type doped region (e.g., an N-type well) of the substrate. Here, the resistor Rpw may collectively refer to a first resistor Rpw1, a second resistor Rpw2, an (n/2)-th resistor Rpwn/2, and the like.

For example, when an Electrostatic Discharge (ESD) event occurs, a breakdown may occur in a reverse bias state between the collector and the base of the NPN-type bipolar junction transistor BJT. A certain voltage drop occurs due to a parasitic resistor Rpw formed in the base region, and the base and the emitter may be switched to a forward bias state. Accordingly, the bipolar junction transistor BJT may be turned on, and a current may start to flow. As such, the parasitic resistor Rpw formed in the base region may determine a turn-on characteristic of the bipolar junction transistor BJT when an ESD event occurs.

In some embodiments of the present disclosure, each of the first bipolar junction transistor BJT1, the second bipolar junction transistor BJT2, and the (n/2)-th bipolar junction transistor BJTn/2 may have a uniform base resistance Rpw. That is, the first resistor Rpw1, the second resistor Rpw2, the (n/2)-th resistor Rpwn/2, and the like may have the same or substantially the same resistance value within a predetermined error range. Due to this, when an ESD event occurs, each active region may exhibit uniform and consistent characteristics, thereby improving an ESD protection efficiency of the semiconductor device 1 and improving reliability. This will be described in detail below.

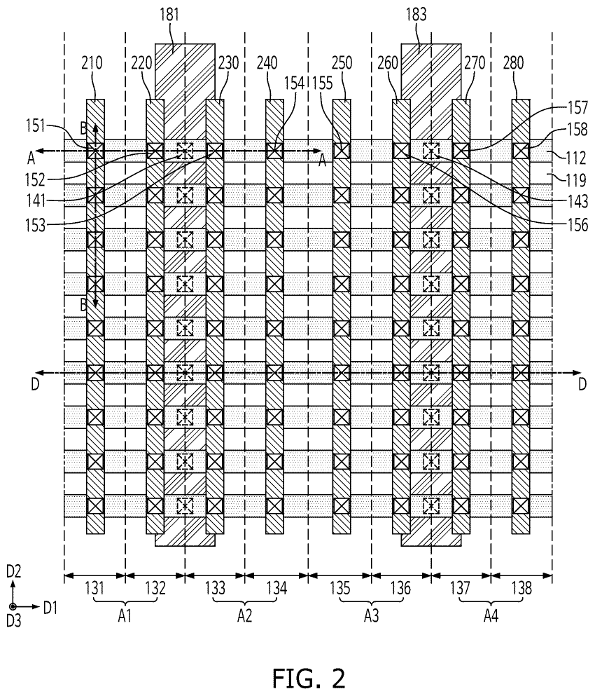

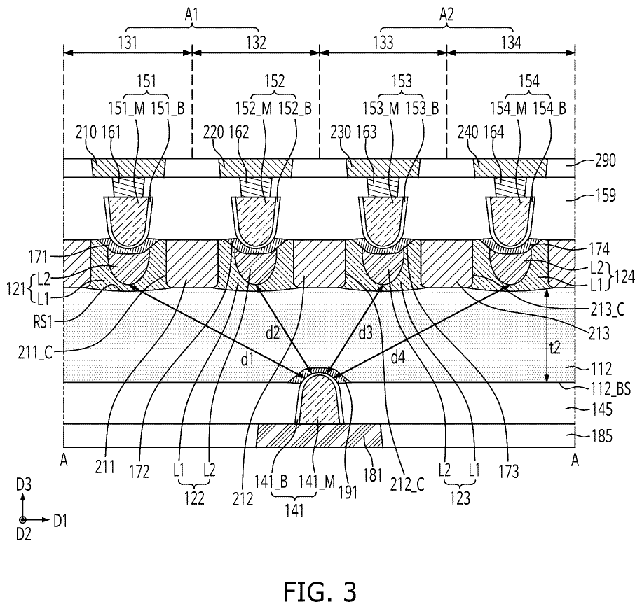

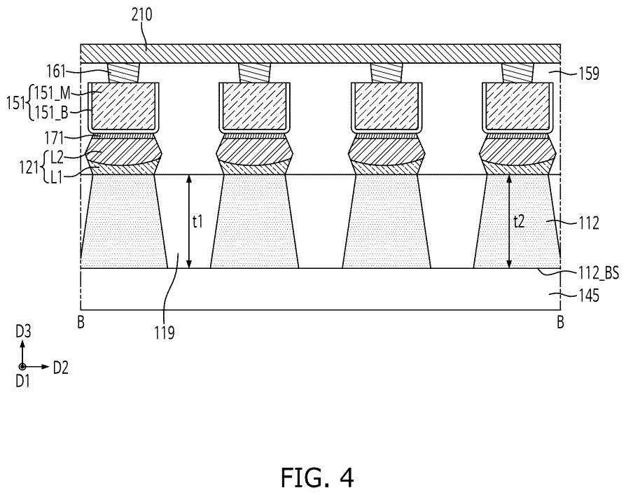

FIG. 2 is a plan view illustrating a semiconductor device according to some embodiments of the present disclosure. FIG. 3 is a cross-sectional view taken along line A-A of FIG. 2. FIG. 4 is a cross-sectional view taken along line B-B of FIG. 2. For convenience of explanation, FIG. 2 is shown with some components such as an impurity pattern and an insulation pattern omitted.

Referring to FIGS. 2 to 4, a semiconductor device according to some embodiments may include a well 112, a shallow trench isolation (STI) structure 119, a first impurity pattern 121 to a fourth impurity pattern 124, a first active region A1 to a fourth active region A4, a first insulation pattern 211 to a third insulation pattern 213, a first bottom contact 141, a second bottom contact 143, a first bottom insulating layer 145, a first top contact 151 to an eighth top contact 158, a first top insulating layer 159, a first bottom wiring structure 181, a second bottom wiring structure 183, a second bottom insulating layer 185, a first top wiring structure 210 to an eighth top wiring structure 280, and a second top insulating layer 290, etc. In FIG. 2, the semiconductor device is illustrated as including the first active region A1 to the fourth active region A4, but the semiconductor device may include five or more active regions, and the present disclosure is not limited thereto.

The well 112 may be a region where at least a portion of a substrate is doped with an impurity. The substrate may include, for example, at least one of silicon (Si), silicon germanium (SiGe), silicon germanium on insulator (SGOI), indium antimonide, lead telluride compound, indium arsenide, indium phosphide, gallium arsenide, or gallium antimonide, but is not limited thereto. The well 112 may extend in a first direction D1 and be doped with a first conductivity type. For example, the well 112 may be a p-type doped region and may include a p-type impurity, boron (B). As another example, the well 112 may be an n-type doped region, and in this case, may include an n-type impurity such as phosphorus (P), arsenic (As), and antimony (Sb).

The shallow trench isolation (STI) structure 119 may be disposed on a side surface of the well 112 to have a shape extending in the first direction D1. A top surface of the STI structure 119 may be in contact with a first top insulating layer 159, and a bottom surface of the STI structure 119 may be in contact with a first bottom insulating layer 145. The top surface of the STI structure 119 may be located on a vertical level corresponding to a top surface of the well 112, and the bottom surface of the STI structure 119 may be located on a vertical level corresponding to a bottom surface of the well 112. For example, the bottom surface of the STI structure 119 may be coplanar with the bottom surface of the well 112.

The STI structure 119 may include an insulating material. For example, the STI structure 119 may include at least one of silicon nitride (SiN), silicon oxynitride (SiON), silicon oxide (SiO2), silicon oxycarbonitride (SiOCN), silicon boronitride (SiBN), silicon oxyboronitride (SiOBN), silicon oxycarbide (SiOC), and combinations thereof. Although the STI structure 119 is illustrated as a single film, this is for convenience of explanation and is not limited thereto. For example, the STI structure 119 may be formed of a plurality of films.

A thickness t2 of the well 112 along a third direction D3 perpendicular to a bottom surface 112_BS of the well 112 may be the same as a thickness t1 of the STI structure 119 along the third direction D3. For example, the thickness t2 of the well 112 may be 20 nm to 80 nm. However, the thickness t2 of the well 112 may be larger or smaller than the thickness t1 of the STI structure 119, and the present disclosure is not limited thereto.

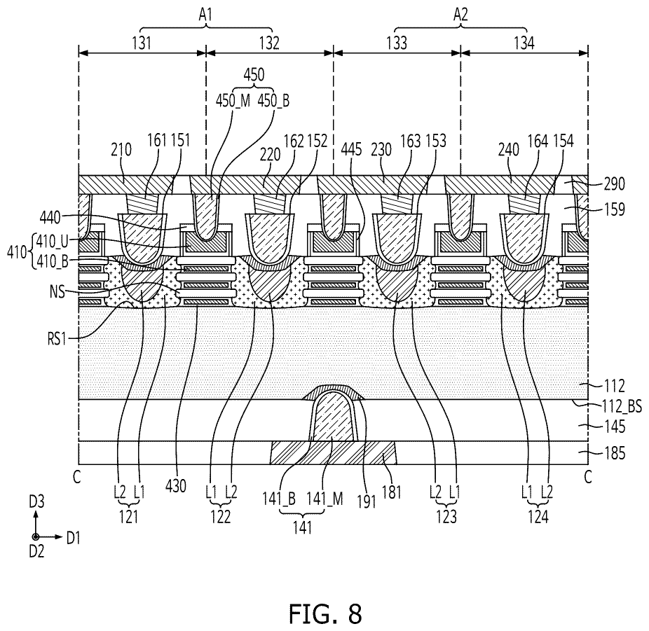

The first impurity pattern 121 to the fourth impurity pattern 124 may be disposed on the well 112. The first impurity pattern 121, the second impurity pattern 122, the third impurity pattern 123, and the fourth impurity pattern 124 may be sequentially disposed along the first direction D1. The first impurity pattern 121 to the fourth impurity pattern 124 may be an epitaxial pattern formed by a selective epitaxial growth process using a substrate and a sheet pattern (e.g., NS of FIG. 8) as a seed.

The first impurity pattern 121 to the fourth impurity pattern 124 may include a semiconductor material. The first impurity pattern 121 to the fourth impurity pattern 124 may include, for example, silicon (Si), silicon-germanium (SiGe), germanium (Ge), silicon carbide (SiC), and the like, but are not limited thereto. For example, the first impurity pattern 121 to the fourth impurity pattern 124 may include a binary compound, a ternary compound including at least two of carbon (C), silicon (Si), germanium (Ge), and tin (Sn), or a compound doped with a group IV element.

The first impurity pattern 121 to the fourth impurity pattern 124 may include an impurity doped in a semiconductor material. The first impurity pattern 121 to the fourth impurity pattern 124 may be doped with an impurity of a second conductivity type different from the impurity of the first conductivity type doped in the well 112. For example, when the well 112 is doped with a p-type, the first impurity pattern 121 to the fourth impurity pattern 124 may be doped with an n-type. As another example, when the well 112 is doped with an n-type, the first impurity pattern 121 to the fourth impurity pattern 124 may be doped with a p-type.

The first impurity pattern 121 to the fourth impurity pattern 124 may include a plurality of films including different materials. In another embodiment, the first impurity pattern 121 to the fourth impurity pattern 124 may include a plurality of layers including the same material and having different concentrations of constituent materials. For example, each of the first impurity pattern 121 to the fourth impurity pattern 124 may include a first layer L1 and a second layer L2 disposed on the first layer L1. The first layer L1 may cover an inner sidewall and a bottom surface of a first recess RS1.

The first layer L1 may be disposed on a sidewall of the first to third insulation patterns 211, 212, 213 and a top surface of the well 112. The second layer L2 may cover a bottom surface and a side surface in the first direction D1 of the first layer L1. That is, the second layer L2 may fill most of the remaining area of the first recess RS1 except for the first layer L1. The first layer L1 and the second layer L2 may be those formed by a selective epitaxial growth process. However, the present disclosure is not limited thereto, and the first impurity pattern 121 to the fourth impurity pattern 124 may be formed as a single film.

A first top contact 151 may be disposed on a top surface of the first impurity pattern 121. The first top contact 151 may penetrate the top surface of the first impurity pattern 121. The first impurity pattern 121 and a first top wiring structure 210 may be electrically connected by the first top contact 151.

In some embodiments, a side surface of the first top contact 151 may have a tapered shape. A slope of the side surface of the first top contact 151 may not be constant. A width of the first top contact 151 in the first direction D1 may increase as a distance from the well 112 increases.

A first top via 161 may be disposed on the first top contact 151. The first top contact 151 and the first top via 161 may penetrate the first top insulating layer 159. The first top via 161 may electrically connect the first impurity pattern 121 and the first top wiring structure 210. A top surface of the first top via 161 may be in contact with a bottom surface of the first top wiring structure 210, and a bottom surface of the first top via 161 may be in contact with a top surface of the first top contact 151.

The first top contact 151 may be formed of a plurality of patterns. The first top contact 151 may include a barrier pattern 151_B and a conductive pattern 151_M disposed within the barrier pattern 151_B. The conductive pattern 151_M may fill a space within the barrier pattern 151_B. The barrier pattern 151_B may be in contact with the first impurity pattern 121, and the conductive pattern 151_M may be in contact with a bottom surface of the first top via 161.

The barrier pattern 151_B of the first top contact 151 may include, for example, at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), or a 2D material. The conductive pattern 151_M of the first top contact 151 may include, for example, at least one of aluminum (Al), copper (Cu), tungsten (W), cobalt (Co), ruthenium (Ru), silver (Ag), gold (Au), manganese (Mn), or molybdenum (Mo).

For a smooth electrical connection between a metal and a semiconductor, for example, a silicide film 171 may be interposed between the first top contact 151 and the first impurity pattern 121. The first top contact 151 may be electrically connected to the first impurity pattern 121 through the silicide film 171. For example, the silicide film 171 may include at least one of titanium-silicide, tantalum-silicide, tungsten-silicide, nickel-silicide, and cobalt-silicide.

A description of a second top contact 152 to a fourth top contact 154 and a second top via 162 to a fourth top via 164 may be the same as the description of the first top contact 151 and the first top via 161, so a duplicate description is omitted.

The first top insulating layer 159 may be disposed on the first impurity pattern 121 to the fourth impurity pattern 124. A top surface of the first top insulating layer 159 may be disposed at the same vertical level as a top surface of each of the first top via 161 to the fourth top via 164. However, the present disclosure is not limited thereto. The first top insulating layer 159 may include, for example, at least one of silicon oxide (SiO), silicon nitride (SiN), silicon oxynitride (SiON), and a low-k material. The low-k material may include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), Poly TetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica, or a combination thereof, but is not limited thereto.

A second top insulating layer 290 may be disposed on the first top insulating layer 159. The second top insulating layer 290 may cover the top surface of the first top insulating layer 159. The second top insulating layer 290 may include, for example, at least one of silicon oxide, silicon nitride, silicon oxynitride, and a low-k material. A first top wiring structure 210 to a fourth top wiring structure 240 may be disposed in the second top insulating layer 290.

The first top wiring structure 210 to the fourth top wiring structure 240 may each be disposed at a higher vertical level than the first impurity pattern 121 to the fourth impurity pattern 124, and may extend in a second direction D2 perpendicular to the first direction D1. The second direction D2 may be a direction parallel to the bottom surface 112_BS of the well 112. The first top wiring structure 210 to the fourth top wiring structure 240 may be disposed at a higher vertical level than the first top insulating layer 159 and disposed in the second top insulating layer 290. Each of the first top wiring structure 210 to the fourth top wiring structure 240 may be disposed on each of the first top contact 151 to the fourth top contact 154. By the first top contact 151 to the fourth top contact 154, each of the first top wiring structure 210 to the fourth top wiring structure 240 may be electrically connected to each of the first impurity pattern 121 to the fourth impurity pattern 124.

The first active region A1 may include a first collector/emitter region 131 including the first impurity pattern 121 and a second collector/emitter region 132 including the second impurity pattern 122. The first active region A1 may include at least one collector region and at least one emitter region.

A second active region A2 may include a third collector/emitter region 133 including the third impurity pattern 123 and a fourth collector/emitter region 134 including the fourth impurity pattern 124. The second active region A2 may include at least one collector region and at least one emitter region.

Based on the first direction D1, the first active region A1 and the second active region A2 may have a structure that is symmetric with respect to the first bottom contact 141. For example, when the first bottom contact 141 is disposed between the second impurity pattern 122 and the third impurity pattern 123, it may have a structure in which the first collector/emitter region 131 is a collector region, the second collector/emitter region 132 is an emitter region, the third collector/emitter region 133 is an emitter region, and the fourth collector/emitter region 134 is a collector region. As another example, when the first bottom contact 141 is disposed between the second impurity pattern 122 and the third impurity pattern 123, it may have a structure in which the first collector/emitter region 131 is an emitter region, the second collector/emitter region 132 is a collector region, the third collector/emitter region 133 is a collector region, and the fourth collector/emitter region 134 is an emitter region. However, the first active region A1 and the second active region A2 may have a structure that is not symmetric with respect to the first bottom contact 141, for example, a structure in which the first collector/emitter region 131 is a collector region, the second collector/emitter region 132 is an emitter region, the third collector/emitter region 133 is a collector region, and the fourth collector/emitter region 134 is an emitter region, and the present disclosure is not limited thereto.

The first bottom contact 141 is disposed on the bottom surface 112_BS of the well 112 and may be electrically connected to ground. The first bottom contact 141 may penetrate the bottom surface 112_BS of the well 112. One end of the first bottom contact 141 may be disposed within the well 112. The first bottom contact 141 may be electrically connected to the well 112. The first bottom contact 141 may electrically connect between the well 112 and a first bottom wiring structure 181.

A width of the first bottom contact 141 along the first direction D1 may be smaller than a width of the first bottom wiring structure 181 along the first direction D1. In some embodiments, a side surface of the first bottom contact 141 may have a slope. The slope of the side surface of the first bottom contact 141 may not be constant. For example, the width of the first bottom contact 141 in the first direction D1 may decrease as a distance from the first bottom wiring structure 181 increases.

The first bottom contact 141 may include a barrier pattern 141_B and a conductive pattern 141_M disposed within the barrier pattern 141_B. The conductive pattern 141_M may fill a space within the barrier pattern 141_B. That is, the first bottom contact 141 may include the conductive pattern 141_M and the barrier pattern 141_B surrounding the conductive pattern 141_M. The barrier pattern 141_B may be in contact with the well 112, and the conductive pattern 141_M may be in contact with a top surface of the first bottom wiring structure 181. A description of the materials of the barrier pattern 141_B and the conductive pattern 141_M of the first bottom contact 141 may be the same as the description of the barrier pattern 151_B and the conductive pattern 151_M of the first top contact 151.

For a smooth electrical connection between a metal and a semiconductor, for example, a silicide film 191 may be interposed between the first bottom contact 141 and the well 112. The first bottom contact 141 may be electrically connected to the well 112 through the silicide film 191. For example, the silicide film 191 may include at least one of titanium-silicide, tantalum-silicide, tungsten-silicide, nickel-silicide, and cobalt-silicide.

From a plan view perspective, the first bottom contact 141 may be disposed between the first impurity pattern 121 and the fourth impurity pattern 124. That is, when viewed from a third direction D3, the first bottom contact 141 may be disposed between the first impurity pattern 121 and the fourth impurity pattern 124. From a plan view perspective, the first bottom contact 141 may be disposed between the second impurity pattern 122 and the third impurity pattern 123. That is, when viewed from the third direction D3, the first bottom contact 141 may be disposed between the second impurity pattern 122 and the third impurity pattern 123. For example, the first bottom contact 141 may be disposed at a boundary between the first active region A1 and the second active region A2. However, the present disclosure is not limited thereto, and the first bottom contact 141 may be disposed in either the first active region A1 or the second active region A2.

A distance d2 between the first bottom contact 141 and the second impurity pattern 122 may be the same as a distance d3 between the first bottom contact 141 and the third impurity pattern 123. Therefore, a resistance existing between the first bottom contact 141 and the second impurity pattern 122 may be the same as a resistance existing between the first bottom contact 141 and the third impurity pattern 123. Also, a distance d1 between the first bottom contact 141 and the first impurity pattern 121 may be the same as a distance d4 between the first bottom contact 141 and the fourth impurity pattern 124. Therefore, a resistance existing between the first bottom contact 141 and the first impurity pattern 121 may be the same as a resistance existing between the first bottom contact 141 and the fourth impurity pattern 124.

The first bottom insulating layer 145 may be disposed on the bottom surface 112_BS of the well 112. A bottom surface of the first bottom insulating layer 145 may be located on the same vertical level as a bottom surface of the first bottom contact 141. However, the present disclosure is not limited thereto. Although the first bottom insulating layer 145 is illustrated as a single film, this is for convenience of explanation and is not limited thereto. For example, the first bottom insulating layer 145 may be formed of a plurality of films. The first bottom insulating layer 145 may include, for example, at least one of silicon carbonitride (SiCN), silicon oxycarbide (SiCO), silicon oxide (SiO), silicon nitride (SiN), silicon oxynitride (SiON), and a low-k material.

A second bottom insulating layer 185 may be disposed on a bottom surface of the first bottom insulating layer 145. The second bottom insulating layer 185 may cover the bottom surface of the first bottom insulating layer 145. Although the second bottom insulating layer 185 is illustrated as a single film, this is for convenience of explanation and is not limited thereto. For example, the second bottom insulating layer 185 may be formed of a plurality of films. A material of the second bottom insulating layer 185 may be the same as a material of the second top insulating layer 290. The first bottom wiring structure 181 may be disposed in the second bottom insulating layer 185.

The first bottom wiring structure 181 is disposed on the bottom surface of the first bottom insulating layer 145 and may extend in the second direction D2 perpendicular to the first direction D1. The first bottom wiring structure 181 may at least partially overlap with the second impurity pattern 122 in a third direction D3 perpendicular to each of the first direction D1 and the second direction D2. The third direction D3 may be a direction perpendicular to the bottom surface 112_BS of the well 112. Also, the first bottom wiring structure 181 may at least partially overlap with the third impurity pattern 123 in the third direction D3. For example, the first bottom wiring structure 181 may at least partially overlap with the second impurity pattern 122 and the third impurity pattern 123 in the third direction D3. A top surface of the first bottom wiring structure 181 may be in contact with a bottom surface of the first bottom contact 141.

A semiconductor device according to some embodiments may include the first insulation pattern 211, a second insulation pattern 212, and a third insulation pattern 213.

The first insulation pattern 211 may be disposed on the well 112, between the first impurity pattern 121 and the second impurity pattern 122. The first insulation pattern 211 may be disposed at the same vertical level as the first impurity pattern 121 and the second impurity pattern 122. The first insulation pattern 211 may be disposed on the top surface of the well 112. The first insulation pattern 211 may be disposed between the well 112 and the first top insulating layer 159.

A sidewall 211_C of the first insulation pattern 211 may extend parallel to the third direction D3. However, the present disclosure is not limited thereto, and the sidewall 211_C of the first insulation pattern 211 may have a slope. The sidewall 211_C of the first insulation pattern 211 may be in contact with the first impurity pattern 121 and the second impurity pattern 122.

The first insulation pattern 211 may include an insulating material. The first insulation pattern 211 may include, for example, any one of silicon oxide (SiO), silicon nitride (SiN), silicon oxynitride (SiON), silicon carbide (SiC), silicon carbonitride (SiCN), and silicon oxycarbonitride (SiOCN). However, the present disclosure is not limited thereto. For example, a material of the first insulation pattern 211 may be the same as a material of the first top insulating layer 159.

The second insulation pattern 212 may be disposed on the well 112, between the second impurity pattern 122 and the third impurity pattern 123. The second insulation pattern 212 may be disposed at the same vertical level as the second impurity pattern 122 and the third impurity pattern 123. The second insulation pattern 212 may be disposed on the top surface of the well 112. The second insulation pattern 212 may be disposed between the well 112 and the first top insulating layer 159. A material of the second insulation pattern 212 may be the same as the material of the first insulation pattern 211.

The third insulation pattern 213 may be disposed on the well 112, between the third impurity pattern 123 and the fourth impurity pattern 124. The third insulation pattern 213 may be disposed at the same vertical level as the third impurity pattern 123 and the fourth impurity pattern 124. The third insulation pattern 213 may be disposed on the top surface of the well 112. The third insulation pattern 213 may be disposed between the well 112 and the first top insulating layer 159. A material of the third insulation pattern 213 may be the same as the material of the first insulation pattern 211.

From this configuration, because each of the first active region A1 and the second active region A2 of the semiconductor device according to some embodiments may have a structure that is symmetric with respect to the first bottom contact 141, a resistance inherent in the well 112 existing in a path between each of the first active region A1 and the second active region A2 and the first bottom contact 141 may be substantially uniform. Due to this, when an ESD event occurs, each active region A1, A2 may exhibit uniform and consistent characteristics, thereby improving the reliability of the semiconductor device.

Meanwhile, a third active region A3 and a fourth active region A4, the second bottom contact 143, a fifth top contact 155 to an eighth top contact 158, a second bottom wiring structure 183, and a fifth top wiring structure 250 to an eighth top wiring structure 280 shown in FIG. 2 may have the same or substantially the same structure as the previously described first active region A1 and second active region A2, the first bottom contact 141, the first top contact 151 to the fourth top contact 154, the first bottom wiring structure 181, and the first top wiring structure 210 to the fourth top wiring structure 240, and a duplicate description is omitted.

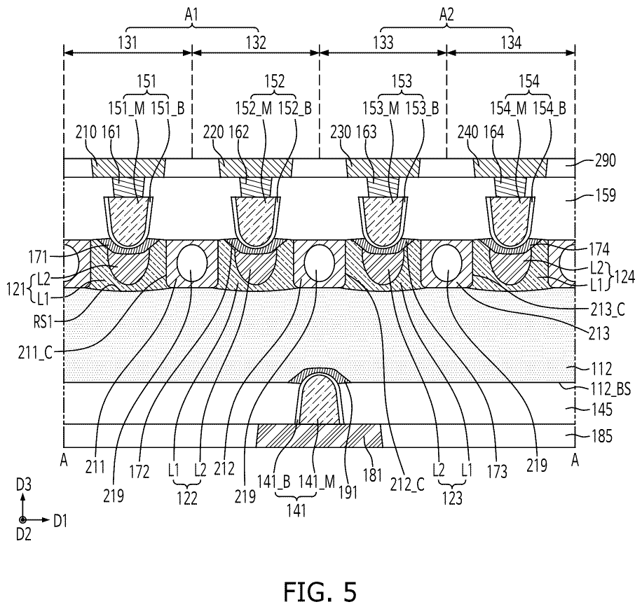

FIG. 5 is a diagram illustrating a semiconductor device according to some embodiments of the present disclosure. For convenience of explanation, the description will focus on configurations different from those described in FIGS. 1 to 4.

Referring to FIG. 5, in a semiconductor device according to some embodiments, each of the first insulation pattern 211 to the third insulation pattern 213 may include a void 219 therein.

The void 219 may be a state where no solid exists, and may be a gas phase such as air or a vacuum state. The void 219 may be circular or elliptical. When the void 219 is elliptical, a major axis of the void 219 may extend parallel to the third direction D3. However, the present disclosure is not limited thereto, and the major axis of the void 219 may not be parallel to the third direction D3. Although FIG. 5 illustrates the void 219 as being surrounded by the insulation patterns 211, 212, 213, the void 219 may be formed on a top surface of the insulation patterns 211, 212, 213 and be surrounded by the insulation patterns 211, 212, 213 and the first top insulating layer 159.

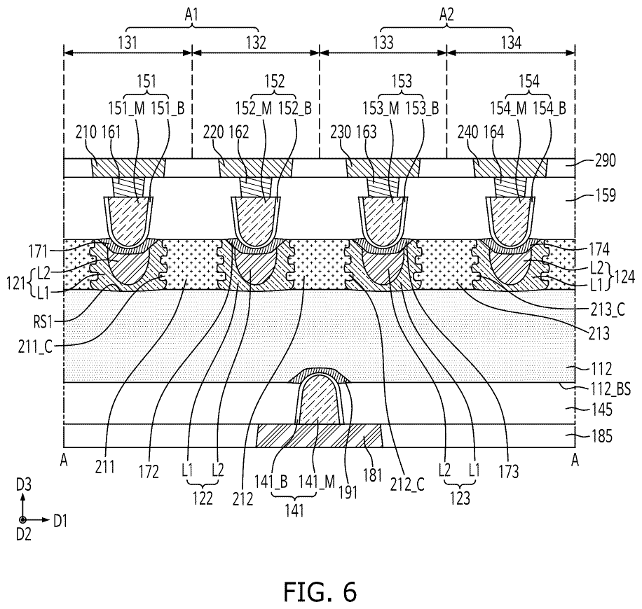

FIG. 6 is a diagram illustrating a semiconductor device according to some embodiments of the present disclosure. For convenience of explanation, the description will focus on configurations different from those described in FIGS. 1 to 4.

Referring to FIG. 6, in a semiconductor device according to some embodiments, a sidewall 211_C, 212_C, 213_C in the first direction D1 of each of the first insulation pattern 211 to the third insulation pattern 213 may include a region where concave and convex shapes are alternately repeated.

For example, the sidewall 211_C of the first insulation pattern 211 may include a sidewall protruding toward the first impurity pattern 121 and the second impurity pattern 122, and a concave sidewall. A sidewall 212_C of the second insulation pattern 212 may include a sidewall protruding toward the second impurity pattern 122 and the third impurity pattern 123, and a concave sidewall. A sidewall 213_C of the third insulation pattern 213 may include a sidewall protruding toward the third impurity pattern 123 and the fourth impurity pattern 124, and a concave sidewall. A shape of the sidewall 211_C, 212_C, 213_C of each of the first insulation pattern 211 to the third insulation pattern 213 may be formed by removing a sheet pattern NS and a gate electrode 410 of FIG. 8.

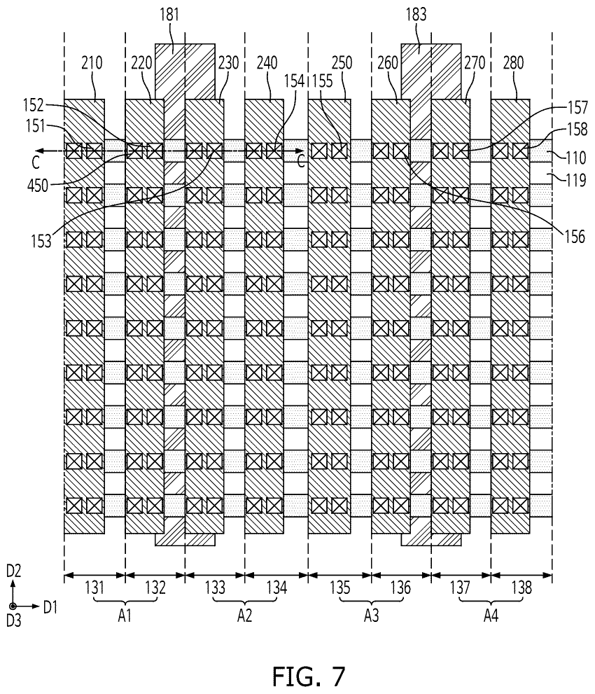

FIGS. 7 and 8 are diagrams illustrating a semiconductor device according to some embodiments of the present disclosure. For reference, FIG. 7 is a plan view of a semiconductor device according to some embodiments, and FIG. 8 may be a cross-sectional view taken along line C-C of FIG. 7. For convenience of explanation, the description will focus on configurations different from those described in FIGS. 1 to 4.

Referring to FIGS. 7 and 8, a semiconductor device according to some embodiments may further include a plurality of sheet patterns NS, a gate electrode 410, a gate insulating layer 430, a gate spacer 445, a gate capping pattern 440, and a gate contact 450, as compared to the semiconductor device described in FIGS. 1 to 4.

The plurality of sheet patterns NS may be disposed on the well 112, between each of the first impurity pattern 121 to the fourth impurity pattern 124. The plurality of sheet patterns NS may be spaced apart from the well 112 in the third direction D3. Each of the plurality of sheet patterns NS may be spaced apart from one another in the third direction D3. In some embodiments, the sheet pattern NS may have a nanosheet shape. Although three sheet patterns NS are illustrated, the present disclosure is not limited thereto.

The sheet pattern NS may include one of an elemental semiconductor material, silicon (Si), silicon germanium (SiGe), a group IV-IV compound semiconductor, or a group III-V compound semiconductor. The group IV-IV compound semiconductor may be, for example, a binary compound or a ternary compound including at least two of carbon (C), silicon (Si), germanium (Ge), and tin (Sn). The group III-V compound semiconductor may be, for example, one of a binary compound, a ternary compound, or a quaternary compound formed by combining at least one of aluminum (Al), gallium (Ga), or indium (In) as a group III element with one of phosphorus (P), arsenic (As), and antimony (Sb) as a group V element.

The gate electrode 410 is disposed on the well 112 and may extend in a second direction D2. The gate electrode 410 may intersect (e.g., be perpendicular to) the well 112. The gate electrode 410 may surround the plurality of sheet patterns NS. The gate electrode 410 may surround four surfaces of the sheet pattern NS. For example, the gate electrode 410 may surround a top surface, a bottom surface, and both side surfaces of the sheet pattern NS. Here, the top surface and the bottom surface of the sheet pattern NS mean surfaces facing one another in the third direction D3, and the both side surfaces of the sheet pattern NS may mean surfaces facing one another in the second direction D2.

The gate electrode 410 may include a top gate electrode 410_U and a bottom gate electrode 410_B. The bottom gate electrode 410_B may be disposed between sheet patterns NS adjacent to one another in the third direction D3, and between the well 112 and a sheet pattern NS disposed at a lowermost portion among the plurality of sheet patterns NS. The top gate electrode 410_U may be disposed on a top surface of a sheet pattern NS disposed at an uppermost portion among the plurality of sheet patterns NS. In some embodiments, a height of the top gate electrode 410_U in the third direction D3 may be greater than a height of the bottom gate electrode 410_B in the third direction D3. However, the present disclosure is not limited thereto.

The gate electrode 410 may include at least one of a metal, a metal alloy, a conductive metal nitride, a metal silicide, a doped semiconductor material, a conductive metal oxide, or a conductive metal oxynitride. The gate electrode 410 may include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or a combination thereof, but is not limited thereto.

The gate insulating layer 430 may be disposed between the gate electrode 410 and the plurality of sheet patterns NS, between the gate electrode 410 and the well 112, and between the gate electrode 410 and the plurality of impurity patterns 121, 122, 123, 124. The gate insulating layer 430 may be disposed between the top gate electrode 410_U and a sheet pattern NS disposed at an uppermost portion among the plurality of sheet patterns NS. The gate insulating layer 430 may be disposed between the bottom gate electrode 410_B and the sheet pattern NS.

In some embodiments, the gate insulating layer 430 may include a plurality of films. For example, the gate insulating layer 430 may include an interface insulating layer and a high-k insulating layer. The interface insulating layer may include, for example, silicon oxide. The high-k insulating layer may include a high-k material having a dielectric constant greater than that of the interface insulating layer. The high-k insulating layer may include, for example, at least one of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The gate spacer 445 may be disposed on a side surface of the top gate electrode 410_U. For example, the gate spacer 445 may extend along the side surface of the top gate electrode 410_U. The gate spacer 445 may not be located between sheet patterns NS adjacent in the third direction D3.

The gate spacer 445 may include, for example, at least one of silicon nitride (SiN), silicon oxynitride (SiON), silicon oxide (SiO2), silicon oxycarbonitride (SiOCN), silicon boronitride (SiBN), silicon oxyboronitride (SiOBN), silicon oxycarbide (SiOC), or a combination thereof. Although the gate spacer 445 is illustrated as a single film, this is for convenience of explanation and is not limited thereto.

The gate capping pattern 440 may be disposed on a top surface of the top gate electrode 410_U and a top surface of the gate spacer 445. The gate capping pattern 440 may cover the top surface of the top gate electrode 410_U. Although the gate capping pattern 440 is illustrated as being in contact with the top surface of the gate spacer 445, the present disclosure is not limited thereto. For example, the gate capping pattern 440 may be disposed between the gate spacers 445 and be in contact with one surface of the gate spacer 445. A top surface of the gate capping pattern 440 may be located at a lower vertical level than a top surface of the top contacts 151, 152, 153, 154.

The gate capping pattern 440 may include, for example, at least one of silicon nitride (SiN), silicon oxynitride (SiON), silicon carbonitride (SiCN), silicon oxycarbonitride (SiOCN), or a combination thereof. The gate capping pattern 440 may include a material having an etch selectivity with respect to the first top insulating layer 159.

The gate contact 450 may penetrate a top surface of the first top insulating layer 159, the gate capping pattern 440, and the gate electrode 410. For example, the gate contact 450 may penetrate the top surface of the top gate electrode 410_U. One end of the gate contact 450 may be disposed within the top gate electrode 410_U. The gate contact 450 may be connected to the gate electrode 410. The gate contact 450 may be connected to the top wiring structures 210, 220, 230, 240. A top surface of the gate contact 450 may be in contact with a bottom surface of the top wiring structures 210, 220, 230, 240. The top wiring structures 210, 220, 230, 240 may be connected to at least one of the gate contact 450 and the top vias 161, 162, 163, 164. The gate contact 450 may electrically connect the gate electrode 410 and the top wiring structures 210, 220, 230, 240.

The gate contact 450 may include a barrier pattern 450_B and a conductive pattern 450_M disposed within the barrier pattern 450_B. A description of the materials of the barrier pattern 450_B and the conductive pattern 450_M of the gate contact 450 may be the same as the description of the barrier pattern 151_B and the conductive Pattern 151_M of the first top contact 151.

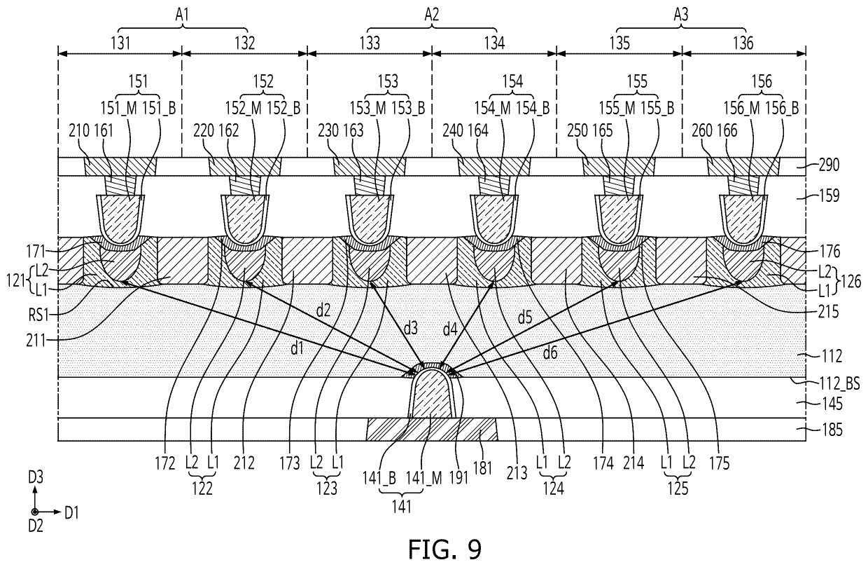

FIG. 9 is a diagram illustrating a semiconductor device according to some embodiments of the present disclosure. For reference, FIG. 9 may be an exemplary cross-sectional view illustrating a semiconductor device according to some embodiments. For convenience of explanation, the description will focus on configurations different from those described in FIGS. 1 to 4.

Referring to FIG. 9, a semiconductor device according to some embodiments may include the first active region A1, the second active region A2, a third active region A3, and the first bottom contact 141. That is, the first bottom contact 141 may be formed corresponding to three or more active regions, and the present disclosure is not limited thereto.

From a plan view perspective, the first bottom contact 141 may be disposed between the third impurity pattern 123 and the fourth impurity pattern 124. When viewed from the third direction D3, the first bottom contact 141 may be disposed between the third impurity pattern 123 and the fourth impurity pattern 124. That is, the first bottom contact 141 may be disposed at a boundary of the third collector/emitter region 133 and the fourth collector/emitter region 134.

A distance d3 between the first bottom contact 141 and the third impurity pattern 123 may be the same as a distance d4 between the first bottom contact 141 and the fourth impurity pattern 124. A distance d2 between the first bottom contact 141 and the second impurity pattern 122 may be the same as a distance d5 between the first bottom contact 141 and a fifth impurity pattern 125. Also, a distance d1 between the first bottom contact 141 and the first impurity pattern 121 may be the same as a distance d6 between the first bottom contact 141 and a sixth impurity pattern 126.

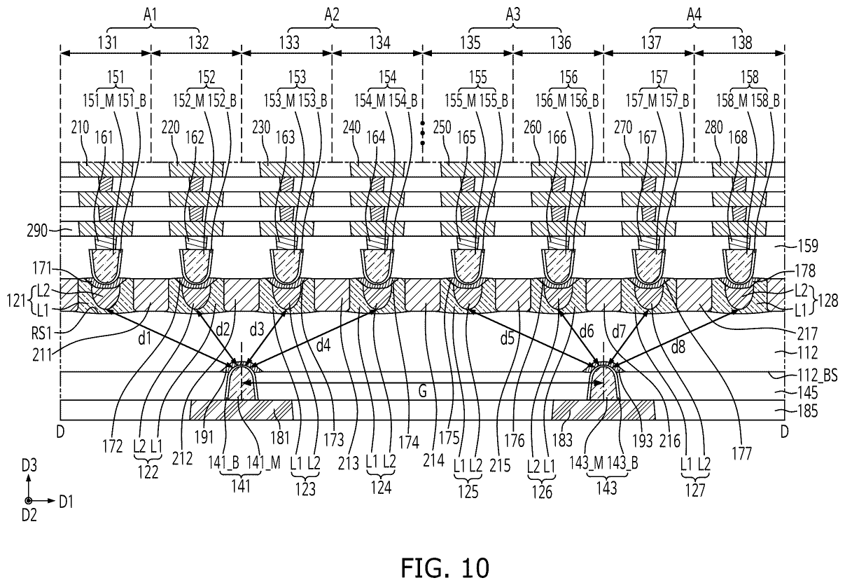

FIG. 10 is a diagram illustrating a semiconductor device according to some embodiments of the present disclosure. For reference, FIG. 10 may be a cross-sectional view taken along line D-D of FIG. 2. For convenience of explanation, the description will focus on configurations different from those described in FIGS. 1 to 4.

Referring to FIG. 10, a semiconductor device according to some embodiments may include a plurality of impurity patterns 121, 122, 123, 124, 125, 126, 127, 128, a plurality of active regions A1, A2, A3, A4, and a plurality of bottom contacts 141, 143.

The plurality of impurity patterns 121, 122, 123, 124, 125, 126, 127, 128 may be disposed on the well 112 along the first direction D1. The plurality of impurity patterns 121, 122, 123, 124, 125, 126, 127, 128 may include the first impurity pattern 121, the second impurity pattern 122, the third impurity pattern 123, the fourth impurity pattern 124, the fifth impurity pattern 125, the sixth impurity pattern 126, a seventh impurity pattern 127, and an eighth impurity pattern 128.

The plurality of active regions A1, A2, A3, A4 may include a collector region and an emitter region including each of the plurality of impurity patterns 121, 122, 123, 124, 125, 126, 127, 128 and disposed along the first direction D1. The plurality of active regions A1, A2, A3, A4 may include the first collector/emitter region 131, the second collector/emitter region 132, the third collector/emitter region 133, the fourth collector/emitter region 134, a fifth collector/emitter region 135, a sixth collector/emitter region 136, a seventh collector/emitter region 137, and an eighth collector/emitter region 138.

Each of the plurality of bottom contacts 141, 143 is disposed on the bottom surface 112_BS of the well 112 and may be electrically connected to ground. For example, the plurality of bottom contacts 141, 143 may include the first bottom contact 141 and the second bottom contact 143. The plurality of bottom contacts 141, 143 may be disposed to have a periodicity along the first direction D1. The plurality of bottom contacts 141, 143 may be disposed to be spaced apart from one another at a preset interval G along the first direction D1. For example, the first bottom contact 141 and the second bottom contact 143 may be disposed to be spaced apart from one another at the preset interval G along the first direction D1.

The preset interval G may correspond to a length in the first direction D1 of an even number of active regions among the plurality of active regions A1, A2, A3, A4. For example, the preset interval G may correspond to a length in the first direction of two active regions among the plurality of active regions A1, A2, A3, A4.

The distance d2 between the first bottom contact 141 and the second impurity pattern 122 may be the same as the distance d3 between the first bottom contact 141 and the third impurity pattern 123. The distance d1 between the first bottom contact 141 and the first impurity pattern 121 may be the same as the distance d4 between the first bottom contact 141 and the fourth impurity pattern 124.

A distance d6 between the second bottom contact 143 and the sixth impurity pattern 126 may be the same as a distance d7 between the second bottom contact 143 and the seventh impurity pattern 127. A distance d5 between the second bottom contact 143 and the fifth impurity pattern 125 may be the same as a distance d8 between the second bottom contact 143 and the eighth impurity pattern 128.

The top wiring structures 210, 220, 230, 240, 250, 260, 270, 280 may include a plurality of wirings and a plurality of vias. The top wiring structures 210, 220, 230, 240, 250, 260, 270, 280 may have a multi-layered structure in which the plurality of wirings and the plurality of vias are stacked in the third direction D3. The plurality of wirings may be electrically connected to one another through the plurality of vias. The plurality of wirings may include the same or different conductive materials. For example, the plurality of wirings may include at least one metal material selected from aluminum, copper, tungsten, molybdenum, ruthenium, and cobalt. Although not illustrated, wirings and vias may be additionally disposed on the top wiring structures 210, 220, 230, 240, 250, 260, 270, 280.

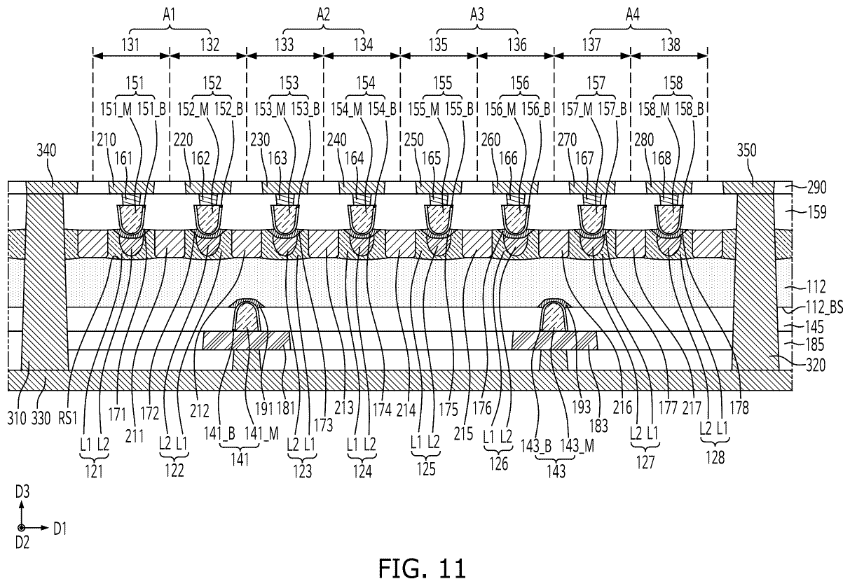

FIG. 11 is a diagram illustrating a semiconductor device according to some embodiments of the present disclosure. For reference, FIG. 10 may be an exemplary cross-sectional view illustrating a semiconductor device according to some embodiments. For convenience of explanation, the description will focus on configurations different from those described in FIGS. 1 to 4.

Referring to FIG. 11, a semiconductor device according to some embodiments may further include through-vias 310, 320.

The through-vias 310, 320 may extend in the third direction D3 perpendicular to the bottom surface 112_BS of the well 112. The through-vias 310, 320 may be disposed on both sides of the plurality of impurity patterns 121, 122, 123, 124, 125, 126, 127, 128 in the first direction D1. However, the present disclosure is not limited thereto, and for example, one through-via 310, 320 may be disposed on one side of the plurality of impurity patterns 121, 122, 123, 124, 125, 126, 127, 128 in the first direction D1.

The through-vias 310, 320 may penetrate the second bottom insulating layer 185, the first bottom insulating layer 145, the well 112, and the first top insulating layer 159. The through-vias 310, 320 may be connected to top wirings 340, 350 and a bottom wiring 330. The through-vias 310, 320 may electrically connect a portion of the top wiring structures 210, 220, 230, 240, 250, 260, 270, 280 and the bottom wiring structures 181, 183 through the top wirings 340, 350 and the bottom wiring 330.

In some embodiments, the top wirings 340, 350 may be electrically connected to ground. For example, the first bottom contact 141 and the second bottom contact 143 may be electrically connected to ground by being connected to the top wirings 340, 350 through the bottom wiring structures 181, 183 and the through-vias 310, 320.

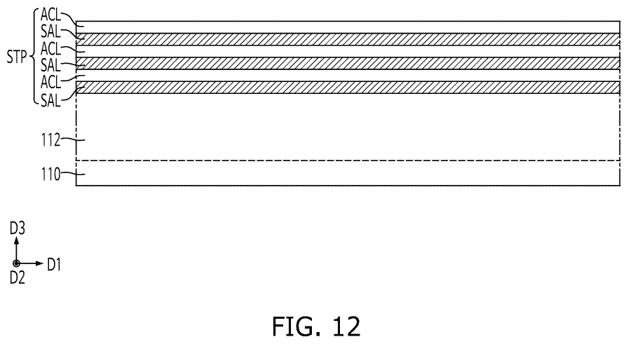

FIGS. 12 to 24 are diagrams illustrating a method of manufacturing a semiconductor device according to some embodiments of the present disclosure. For convenience of explanation, configurations that are the same as those described in FIGS. 1 to 11 are omitted or briefly described.

Referring to FIG. 12, a method of manufacturing a semiconductor device according to some embodiments of the present disclosure may include a step of forming a stacked structure STP on a substrate 110. At this time, the well 112 may be formed by doping at least a portion of the substrate 110 with an impurity. The stacked structure STP may be formed on the well 112.

The stacked structure STP may be formed by alternately stacking a sacrificial layer SAL and an active layer ACL on the substrate 110. The substrate 110 may be a silicon substrate, or may include another material, for example, silicon germanium (SiGe), silicon germanium on insulator (SGOI), indium antimonide, lead telluride compound, indium arsenide, indium phosphide, gallium arsenide, or gallium antimonide, but is not limited thereto.

The stacked structure STP may include the alternately stacked sacrificial layer SAL and active layer ACL. The sacrificial layer SAL may be disposed at a lowermost portion of the stacked structure STP. The active layer ACL may be disposed at an uppermost portion of the stacked structure STP. The active layer ACL and the sacrificial layer SAL may be formed of materials with different etch selectivities. The active layer ACL may include one of silicon (Si), germanium (Ge), and silicon-germanium (SiGe), and the sacrificial layers SAL may include another one of silicon (Si), germanium (Ge), and silicon-germanium (SiGe). The sacrificial layer SAL may include a material having an etch selectivity with respect to the active layer ACL. For example, the active layer ACL may include silicon (Si), and the sacrificial layers SAL may include silicon-germanium (SiGe).

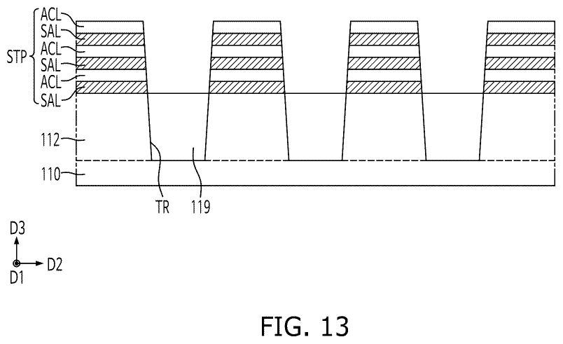

Referring to FIG. 13, a trench TR may be formed by patterning the stacked structure STP. For example, a mask pattern may be formed on the stacked structure STP. The mask pattern may have a line shape or a bar shape extending in a second direction D2. A patterning process may be performed using the mask pattern as an etch mask to form the trench TR.

Subsequently, the STI structure 119 filling the trench TR may be formed. The STI structure 119 may include an insulating material such as a silicon oxide film. The stacked structure STP may be exposed above the STI structure 119. In other words, the stacked structure STP may protrude vertically above the STI structure 119.

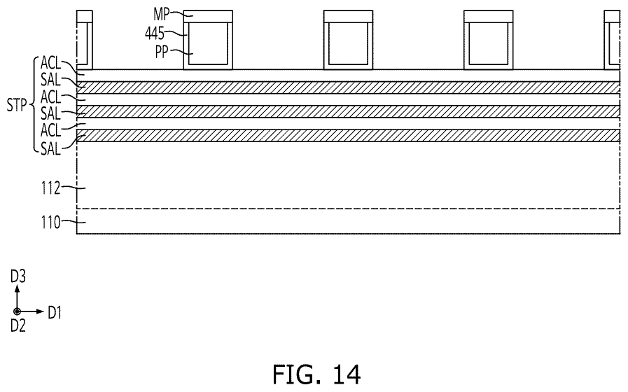

Referring to FIGS. 14 to 16, the impurity patterns 121, 122, 123, 124 may be formed on the well 112.

First, as illustrated in FIG. 14, sacrificial patterns PP and preliminary gate spacers 443 traversing the stacked structure STP may be formed on the substrate 110. Each of the sacrificial patterns PP may be formed in a line shape or a bar shape extending in the second direction D2. The sacrificial patterns PP may be arranged along a first direction D1 at a constant interval. A pair of preliminary gate spacers 443 may be formed on both sidewalls of each of the sacrificial patterns PP. The preliminary gate spacers 443 may be a multi-film including at least two films.

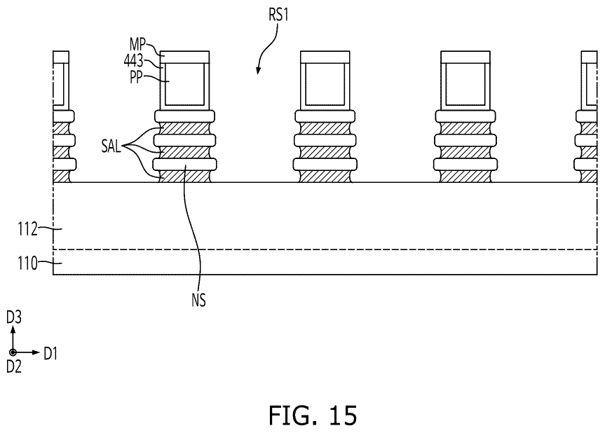

Subsequently, as illustrated in FIG. 15, first recesses RS1 may be formed in the stacked structure STP on the well 112. Specifically, the first recesses RS1 may be formed by etching the stacked structure STP on the well 112 using hard mask patterns MP and the preliminary gate spacers 443 as an etch mask. The first recess RS1 may be formed between a pair of sacrificial patterns PP. A selective etching process for the sacrificial layers SAL exposed by the first recess RS1 is performed, so that the first recess RS1 may have an inner sidewall including a region where convex or concave shapes are alternately repeated in the first direction D1. At this time, in the process of performing the etching process, sheet patterns NS sequentially stacked between the first recesses RS1 adjacent to one another may be respectively formed from the active layers ACL.

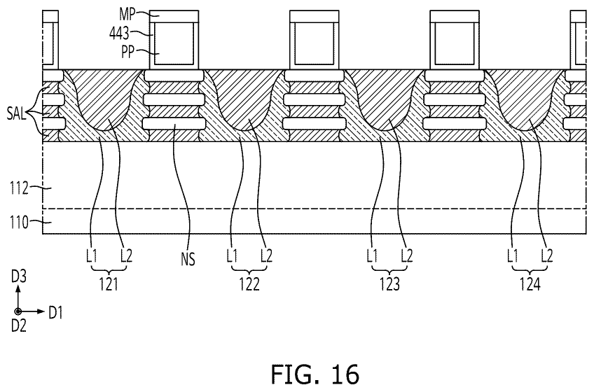

Then, as illustrated in FIG. 16, the impurity patterns 121, 122, 123, 124 may be respectively formed in the first recesses RS1. Specifically, the impurity patterns 121, 122, 123, 124 filling the first recess RS1 may be formed by performing a selective epitaxial growth (SEG) process using a bottom surface and an inner sidewall of the first recess RS1 as a seed layer. The impurity patterns 121, 122, 123, 124 may be grown using the sheet patterns NS and the well 112 (i.e., the substrate 110) exposed by the first recess RS1 as seeds.

The impurity patterns 121, 122, 123, 124 may include the first layer L1 and a second layer L2. First, the first layer L1 may be continuously formed in the first recess RS1. That is, the first layer L1 may extend continuously without a break from a bottom of the first recess RS1 along a side of the sheet pattern NS. The first layer L1 may cover not only the sheet patterns NS but also all of the sacrificial layers SAL.

Then, a second SEG process may be performed using the first layer L1 in the first recess RS1 as a seed layer. Accordingly, the second layer L2 filling the first recess RS1 may be formed. The second SEG process may be performed until the second layer L2 completely fills the first recess RS1.

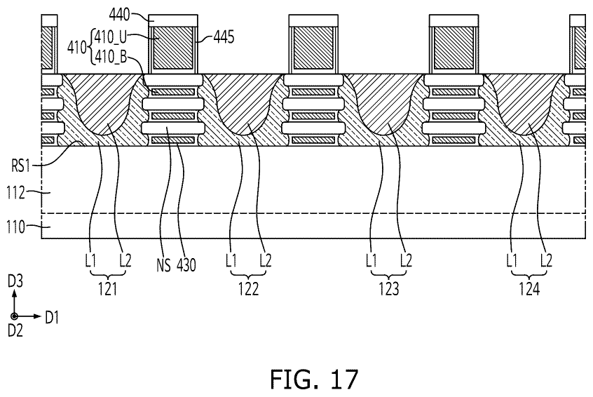

Referring to FIG. 17, the gate electrode 410, the gate insulating layer 430, the gate spacer 445, and the gate capping pattern 440 may be formed.

All of the hard mask patterns MP may be removed. The exposed sacrificial patterns PP may be selectively removed. Also, by performing an etching process that selectively etches the sacrificial layers SAL, only the sacrificial layers SAL can be removed while leaving the sheet patterns NS.

The gate insulating layer 430 may be formed on the exposed sheet patterns NS. The gate insulating layer 430 may be formed to surround each of the sheet patterns NS. The gate electrode 410 may be formed on the gate insulating layer 430. The gate capping pattern 440 may be formed on the gate electrode 410.

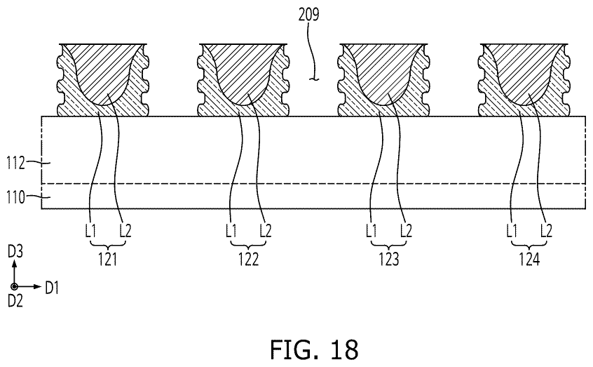

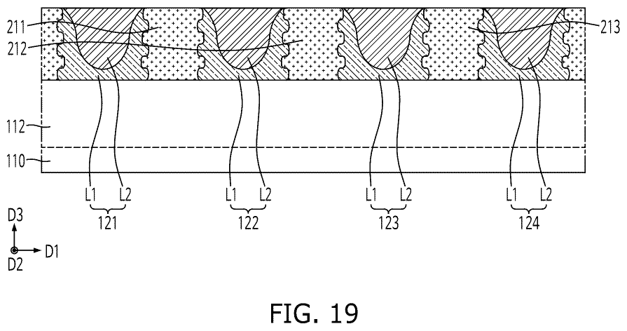

Referring to FIGS. 18 and 19, an etching process may be performed on the plurality of sheet patterns NS, the gate electrode 410, the gate insulating layer 430, the gate spacer 445, and the gate capping pattern 440. Therefore, the plurality of sheet patterns NS, the gate electrode 410, the gate insulating layer 430, the gate spacer 445, and the gate capping pattern 440 may be removed. Accordingly, a hole 209 may be formed between the impurity patterns 121, 122, 123, 124. In some embodiments, a sidewall of the impurity patterns 121, 122, 123, 124 may include a region where convex or concave shapes are alternately repeated in the first direction D1.

The insulation patterns 211, 212, 213 may be formed between the impurity patterns 121, 122, 123, 124. For example, the insulation patterns 211, 212, 213 may be formed by filling an insulating material for forming the insulation patterns 211, 212, 213 inside the hole 209 between the impurity patterns 121, 122, 123, 124. For example, the insulation patterns 211, 212, 213 may include any one of silicon oxide (SiO), silicon nitride (SiN), silicon oxynitride (SiON), silicon carbide (SiC), silicon carbonitride (SiCN), and silicon oxycarbonitride (SiOCN). Specifically, the insulation patterns 211, 212, 213 may include silicon nitride (Si3N4).

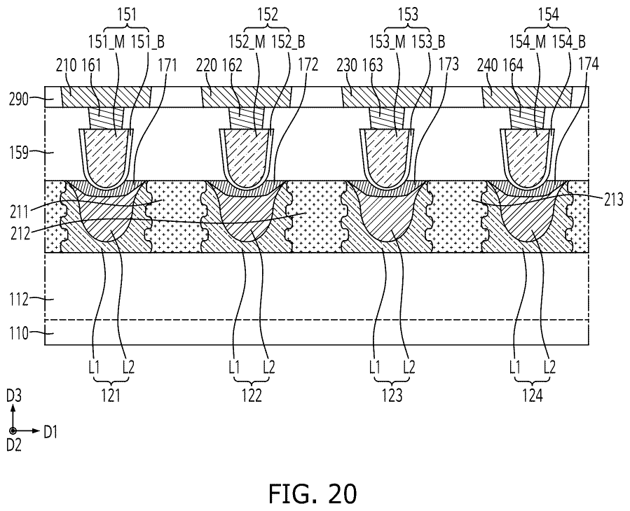

Referring to FIG. 20, the first top insulating layer 159, the top contacts 151, 152, 153, 154, the second top insulating layer 290, and the top wiring structures 210, 220, 230, 240 may be formed.

First, the first top insulating layer 159 may be formed on the impurity patterns 121, 122, 123, 124. An etching process may be performed on the first top insulating layer 159. For example, a portion of the first top insulating layer 159 covered by a mask pattern is not removed, and a portion exposed by the mask pattern may be removed.

A metal material for forming the top contacts 151, 152, 153, 154 may be filled in the portion exposed and etched by the mask pattern. The top contacts 151, 152, 153, 154 may be formed such that a cross-sectional area becomes narrower from a top to a bottom. However, a shape of the top contacts 151, 152, 153, 154 is not limited thereto, and may be formed to have a uniform cross-sectional area.

Before forming the top contacts 151, 152, 153, 154, the silicide film 171 may be first formed on each impurity pattern 121, 122, 123, 124, and the top contacts 151, 152, 153, 154 may be formed on the silicide film 171.

Next, after additionally forming the first top insulating layer 159, the first top via 161 to the fourth top via 164 may be formed in the first top insulating layer 159.

Then, the second top insulating layer 290 may be formed on the first top insulating layer 159. The top wiring structures 210, 220, 230, 240 may be formed in the second top insulating layer 290. The top wiring structures 210, 220, 230, 240 may be disposed on the first top via 161 to the fourth top via 164.

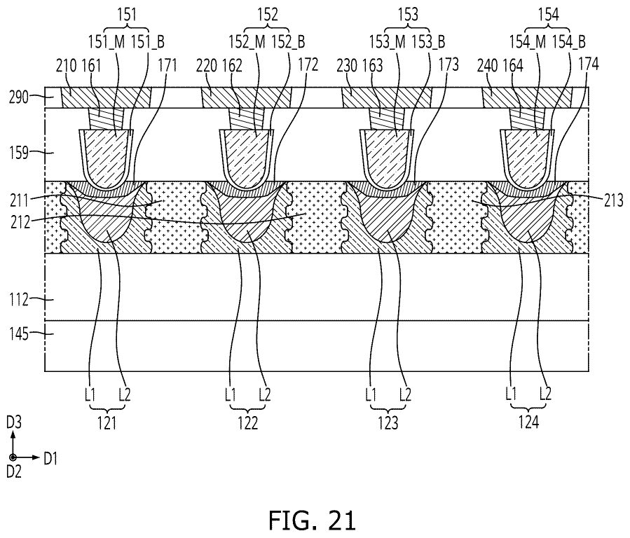

Referring to FIG. 21, a portion of the substrate 110 may be removed. As a portion of the substrate 110 is removed, only a region corresponding to the well 112, which constitutes a part of the substrate 110, may remain. For example, the thickness t2 of the well 112 may be 20 nm-80 nm.

After removing at least a portion of the substrate 110, a planarization process may be performed. The planarization process may be, for example, a Chemical Mechanical Polishing (CMP) process. Subsequently, the first bottom insulating layer 145 may be formed on the bottom surface of the well 112. However, the planarization process may be omitted, and the present disclosure is not limited thereto.

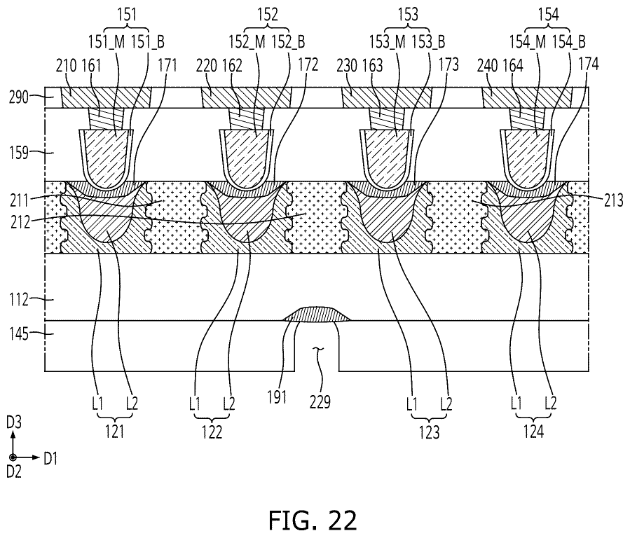

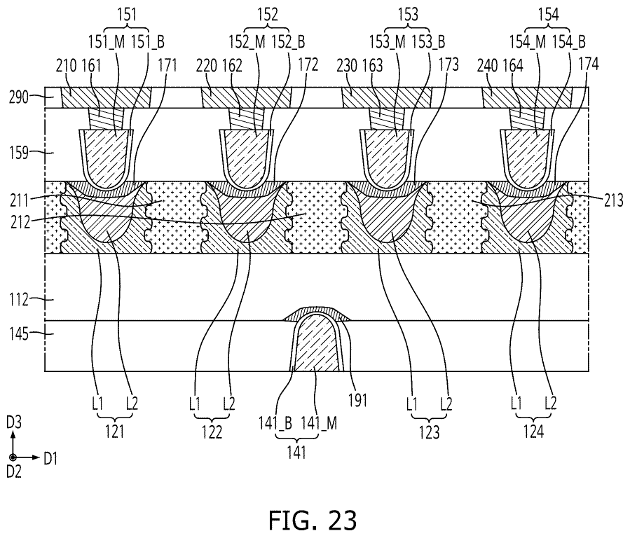

Referring to FIGS. 22 and 23, a portion of the first bottom insulating layer 145 may be etched, and the first bottom contact 141 may be formed.

First, an etching process may be performed on the first bottom insulating layer 145. For example, a portion of the first bottom insulating layer 145 covered by a mask pattern is not removed, and a portion exposed by the mask pattern may be removed. A hole 229 may be formed in the first bottom insulating layer 145.

The well 112 may be exposed through the hole 229. A metal material for forming the first bottom contact 141 may be filled inside the hole 229. Before forming the first bottom contact 141, the silicide film 191 may be first formed on the bottom surface of the well 112, and the first bottom contact 141 may be formed on the silicide film 191.

In some embodiments, from a plan view perspective, the first bottom contact 141 may be disposed between the first impurity pattern 121 and the fourth impurity pattern 124. For example, the first bottom contact 141 may be disposed between the second impurity pattern 122 and the third impurity pattern 123.

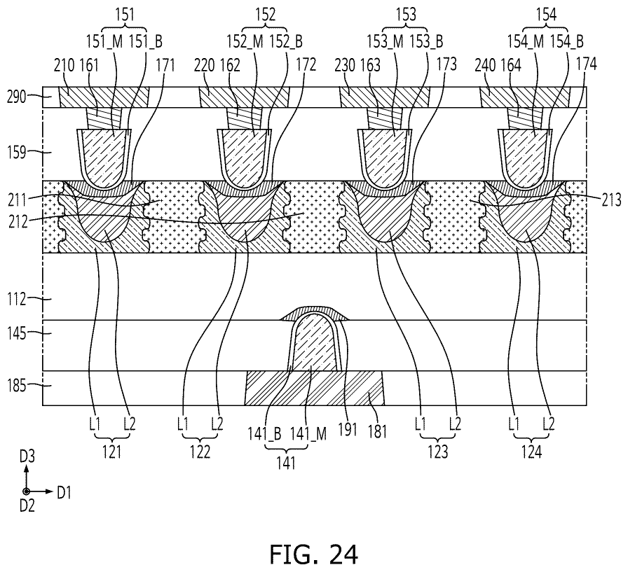

Referring to FIG. 24, the second bottom insulating layer 185 may be formed on the bottom surface of the first bottom insulating layer 145. Then, patterning through an etching process may be performed on the second bottom insulating layer 185. A portion of the second bottom insulating layer 185 may be removed by the etching process. The first bottom wiring structure 181 may be formed in the portion where the second bottom insulating layer 185 was removed. The first bottom wiring structure 181 may be in contact with the bottom surface of the first bottom contact 141. Through this, a semiconductor device as described above with reference to FIG. 6 may be provided.

Although embodiments of the present invention have been described with reference to the accompanying drawings, the present invention is not limited to the above-described embodiments but may be manufactured in various different forms, and it will be understood by those skilled in the art to which the present invention pertains that other specific forms may be implemented without changing the technical spirit or essential features of the present invention. Therefore, it should be understood that the embodiments described above are illustrative in all aspects and not restrictive.

What is claimed is:

1. A semiconductor device, comprising:
a well extending in a first direction and having a first conductivity type;
a first impurity pattern, a second impurity pattern, a third impurity pattern, and a fourth impurity pattern of a second conductivity type sequentially disposed on the well along the first direction;
a first active region comprising a first collector/emitter region comprising the first impurity pattern and a second collector/emitter region comprising the second impurity pattern;
a second active region comprising a third collector/emitter region comprising the third impurity pattern and a fourth collector/emitter region comprising the fourth impurity pattern; and
a first bottom contact disposed on a bottom surface of the well and electrically connected to ground,
wherein, from a plan view perspective, the first bottom contact is disposed between the first impurity pattern and the fourth impurity pattern.

2. The semiconductor device as claimed in claim 1, wherein, from the plan view perspective, the first bottom contact is disposed between the second impurity pattern and the third impurity pattern.

3. The semiconductor device as claimed in claim 2, wherein a distance between the first bottom contact and the second impurity pattern is approximately the same as a distance between the first bottom contact and the third impurity pattern, and
a distance between the first bottom contact and the first impurity pattern is approximately the same as a distance between the first bottom contact and the fourth impurity pattern.

4. The semiconductor device as claimed in claim 2, wherein, based on the first direction, the first collector/emitter region and the second collector/emitter region of the first active region and the third collector/emitter region and the fourth collector/emitter region of the second active region have a structure that is symmetric with respect to the first bottom contact.

5. The semiconductor device as claimed in claim 1, further comprising:
a first bottom insulating layer disposed on the bottom surface of the well;
a second bottom insulating layer disposed on a bottom surface of the first bottom insulating layer; and
a bottom wiring structure disposed on the bottom surface of the first bottom insulating layer and extending in a second direction substantially perpendicular to the first direction,
wherein the first bottom contact is connected to the bottom wiring structure.

6. The semiconductor device as claimed in claim 5, wherein the bottom wiring structure at least partially overlaps with the second impurity pattern and the third impurity pattern in a third direction substantially perpendicular to each of the first direction and the second direction.

7. The semiconductor device as claimed in claim 5, wherein a width of the first bottom contact along the first direction is less than a width of the bottom wiring structure along the first direction.

8. The semiconductor device as claimed in claim 5, further comprising:
a top wiring structure disposed at a higher vertical level than the first impurity pattern, the second impurity pattern, the third impurity pattern, and the fourth impurity pattern, and extending in the second direction;
a top contact connected to a top surface of each of the first impurity pattern, the second impurity pattern, the third impurity pattern, and the fourth impurity pattern; and
a top via connecting the top contact and the top wiring structure.

9. The semiconductor device as claimed in claim 8, further comprising:
a through-via penetrating the second bottom insulating layer, the first bottom insulating layer, the well, and a first top insulating layer disposed on the well, and electrically connecting a portion of the top wiring structure and the bottom wiring structure.

10. The semiconductor device as claimed in claim 1, further comprising a silicide film interposed between the well and the first bottom contact,
wherein the first bottom contact comprises a conductive pattern and a barrier pattern surrounding the conductive pattern.

11. The semiconductor device as claimed in claim 1, further comprising:
a first insulation pattern disposed on the well, between the first impurity pattern and the second impurity pattern;
a second insulation pattern disposed on the well, between the second impurity pattern and the third impurity pattern; and
a third insulation pattern disposed on the well, between the third impurity pattern and the fourth impurity pattern.

12. The semiconductor device as claimed in claim 11, wherein the first insulation pattern, the second insulation pattern, and the third insulation pattern each comprises a void therein.

13. The semiconductor device as claimed in claim 11, wherein a sidewall in the first direction of each of the first insulation pattern, the second insulation pattern, and the third insulation pattern comprises a region where concave and convex shapes are alternately repeated.

14. The semiconductor device as claimed in claim 1, further comprising:
a plurality of sheet patterns disposed on the well, between each of the first impurity pattern, the second impurity pattern, the third impurity pattern, and the fourth impurity pattern, and stacked spaced apart from one another in a third direction substantially perpendicular to the bottom surface of the well; and
a gate electrode surrounding the plurality of sheet patterns.

15. The semiconductor device as claimed in claim 14, further comprising:
a top wiring structure disposed at a higher vertical level than a level of the first impurity pattern, the second impurity pattern, the third impurity pattern, and the fourth impurity pattern, and extending in the second direction;
a top contact connected to a top surface of each of the first impurity pattern, the second impurity pattern, the third impurity pattern, and the fourth impurity pattern;
a top via connecting the top contact and the top wiring structure; and
a gate contact electrically connecting the gate electrode and the top wiring structure.

16. The semiconductor device as claimed in claim 1, further comprising a shallow trench isolation (STI) structure extending in the first direction on a side surface of the well.

17. A semiconductor device, comprising:
a well extending in a first direction and having a first conductivity type;
a plurality of impurity patterns disposed on the well along the first direction and having a second conductivity type;
a plurality of active regions comprising a collector region and an emitter region comprising each of the plurality of impurity patterns and disposed along the first direction; and
a plurality of bottom contacts disposed on a bottom surface of the well and electrically connected to ground,
wherein the plurality of bottom contacts are disposed to be spaced apart from one another at a preset interval along the first direction.

18. The semiconductor device as claimed in claim 17, wherein the preset interval corresponds to a length in the first direction of an even number of active regions among the plurality of active regions.

19. The semiconductor device as claimed in claim 17, wherein the preset interval corresponds to a length in the first direction of two active regions among the plurality of active regions.

20. A semiconductor device, comprising:
a well extending in a first direction and having a first conductivity type;
a first impurity pattern, a second impurity pattern, a third impurity pattern, and a fourth impurity pattern of a second conductivity type sequentially disposed on the well along the first direction;
a first active region comprising a first collector/emitter region comprising the first impurity pattern and a second collector/emitter region comprising the second impurity pattern;
a second active region comprising a third collector/emitter region comprising the third impurity pattern and a fourth collector/emitter region comprising the fourth impurity pattern;
a first bottom contact disposed on a bottom surface of the well and electrically connected to ground;
a first insulation pattern disposed on the well, between the first impurity pattern and the second impurity pattern;
a second insulation pattern disposed on the well, between the second impurity pattern and the third impurity pattern; and
a third insulation pattern disposed on the well, between the third impurity pattern and the fourth impurity pattern,
wherein, from a plan view perspective, the first bottom contact is disposed between the second impurity pattern and the third impurity pattern,
a distance between the first bottom contact and the second impurity pattern is approximately the same as a distance between the first bottom contact and the third impurity pattern,
a distance between the first bottom contact and the first impurity pattern is approximately the same as a distance between the first bottom contact and the fourth impurity pattern, and
a sidewall in the first direction of each of the first insulation pattern, the second insulation pattern, and the third insulation pattern comprises a region where concave and convex shapes are alternately repeated.
